(19) United States
(12) Patent Application Publication
(10) Pub. No.: US 2026/0192522 A1
(43) Pub. Date: Jul. 9, 2026

(54) ADDITIVE MANUFACTURING SYSTEM AND METHOD THAT UTILIZES THERMAL ENERGY GENERATED BY CRYPTOCURRENCY MINING HARDWARE

(71) Applicant: Andrew Prokopyk, Fargo, ND (US)

(72) Inventor: Andrew Prokopyk, Fargo, ND (US)

(21) Appl. No.: 19/438,780

(22) Filed: Jan. 2, 2026

Related U.S. Application Data
(60) Provisional application No. 63/743,461, filed on Jan. 9, 2025.

(51) Int. Cl. B29C 64/295; B33Y 10/00; B33Y 30/00; H05K 7/20

(52) U.S. Cl. CPC B29C 64/295; H05K 7/20763; B33Y 10/00; B33Y 30/00

(57) ABSTRACT

A heatbed assembly for an additive manufacturing system includes a multiple of cryptocurrency mining chips mounted adjacent to a heatsink to transfer thermal energy to the heatsink.

### CROSS REFERENCE TO RELATED APPLICATION[S]

The present disclosure claims priority to U.S. Provisional Patent Disclosure Ser. No. 63/743,461 filed Jan. 9, 2025.

### BACKGROUND

The present disclosure relates to additive manufacturing (3D Printing), and more specifically to thermal management thereof via cryptocurrency mining computer hardware.

Additive manufacturing utilizes thermal energy typically in the range of 40-100° C. to improve component production quality. This is conventionally performed via resistive heating elements.

This background section is intended to introduce the reader to various aspects of art that may be related to various aspects of the present disclosure, which are described and/or claimed below. This discussion is believed to assist the reader with background information to facilitate a better understanding of the various aspects of the present disclosure. Accordingly, it should be understood that these statements are to be read in this light, and not as admissions of prior art.

### SUMMARY

A heatbed assembly for an additive manufacturing system according to one disclosed non-limiting embodiment of the present disclosure includes a heatsink; and a multiple of cryptocurrency mining chips mounted adjacent to the heatsink to transfer thermal energy to the heatsink.

A further embodiment of any of the foregoing embodiments of the present disclosure includes a 3D printer controller in communication with a cryptocurrency mining chip controller, the 3D printer controller operable to control the multiple of cryptocurrency mining chips in response to a desired temperature.

A further embodiment of any of the foregoing embodiments of the present disclosure includes that the heatbed assembly comprises a multiple of tile assemblies.

A further embodiment of any of the foregoing embodiments of the present disclosure includes that the multiple of tile assemblies are arranged in a rectilinear pattern.

A further embodiment of any of the foregoing embodiments of the present disclosure includes that each of the multiple of tile assemblies comprise a multiple of magnets.

A further embodiment of any of the foregoing embodiments of the present disclosure includes that the multiple of cryptocurrency mining chips are mounted to a multiple of printed circuit boards, each of the multiple of printed circuit boards mounted to one of the multiple of tile assemblies.

A further embodiment of any of the foregoing embodiments of the present disclosure includes that a temperature sensor mounted to each of the multiple of tiles, each temperature sensor in communication with the 3D printer controller.

A further embodiment of any of the foregoing embodiments of the present disclosure includes that each of the multiple of tile assemblies comprise a multiple of fins of the heatsink.

A further embodiment of any of the foregoing embodiments of the present disclosure includes that the multiple of fins comprise a multiple of magnet openings located among the multiple of fins adjacent to a bottom surface of each of the respective multiple of tile assemblies to receive and locates a magnet of the multiple of magnets to provide magnetic retention of a removable build plate.

A further embodiment of any of the foregoing embodiments of the present disclosure includes a removable build plate magnetically retained to the heatsink.

A further embodiment of any of the foregoing embodiments of the present disclosure includes a chip interface boss located among the multiple of fins to provides a direct path of contact between one of the multiple of cryptocurrency mining chip a top surface of each of the respective multiple of tile assemblies.

A further embodiment of any of the foregoing embodiments of the present disclosure includes a multiple of cryptocurrency PCB interface bosses among the multiple of fins to provide mounts for a respective cryptocurrency printed circuit board that comprises a multiple of cryptocurrency mining chips.

A further embodiment of any of the foregoing embodiments of the present disclosure includes that thermal management fluid transfer frame system which circulates a di-electric fluid adjacent to the multiple of cryptocurrency mining chips.

A method of heating for an additive manufacturing system according to one disclosed non-limiting embodiment of the present disclosure includes controlling operation of a multiple of cryptocurrency mining chips in response to a desired temperature of an additive manufacturing system.

A further embodiment of any of the foregoing embodiments of the present disclosure includes controlling operation of the cryptocurrency mining chips comprises modifying a clock speed.

A further embodiment of any of the foregoing embodiments of the present disclosure includes controlling a circulation of a di-electric fluid adjacent to the multiple of cryptocurrency mining chips.

The foregoing features and elements may be combined in various combinations without exclusivity, unless expressly indicated otherwise. These features and elements as well as the operation thereof will become more apparent in light of the following description and the accompanying drawings. It should be appreciated that however the following description and drawings are intended to be exemplary in nature and non-limiting.

### BRIEF DESCRIPTION OF THE DRAWINGS

Various features will become apparent to those skilled in the art from the following detailed description of the disclosed non-limiting embodiment. The drawings that accompany the detailed description can be briefly described as follows:

FIG. 1 is an exploded view of an additive manufacturing system according to one disclosed non-limiting embodiment.

FIG. 2 is a side perspective schematic view of an additive manufacturing system according to one disclosed non-limiting embodiment.

FIG. 3 is a top view of a heatbed assembly of an additive manufacturing system according to one disclosed non-limiting embodiment.

FIG. 4 is an exploded view of one tile assembly of a heatbed assembly according to one disclosed non-limiting embodiment.

FIG. 5 is a bottom view of the tile assembly.

FIG. 6 is a bottom view of the heatbed assembly illustrating an orientation of a multiple of tile assemblies.

FIG. 7 is an exploded view of a heatbed assembly with a thermal management fluid transfer frame according to another disclosed non-limiting embodiment.

FIG. 8 is a sectional view of a heatbed assembly with a thermal management fluid transfer circuit.

FIG. 9 is a schematic view of a control system for the additive manufacturing system.

FIG. 10 is a schematic view of a method for operating the additive manufacturing system.

FIG. 11 is an upper oblique view of an additive manufacturing system with a chamber heater according to another disclosed non-limiting embodiment.

### DETAILED DESCRIPTION

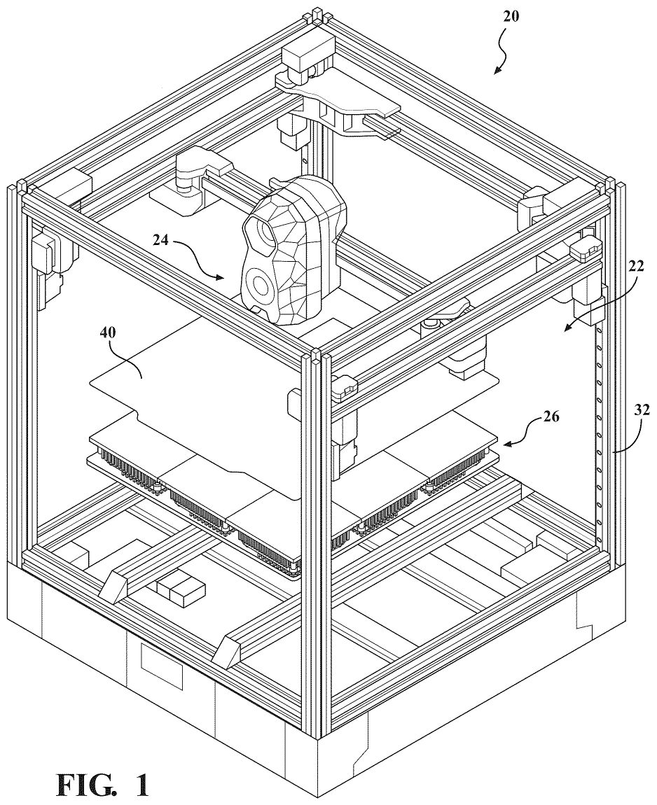

FIG. 1 schematically illustrates an additive manufacturing system 20 that includes a heatable build chamber 22, an extrusion head 24, a heatbed assembly 26, a gantry 28 which moves the extrusion head 24 in an X, Y and/or Z plane relative to the heatbed assembly 26, and a frame 32. Alternatively, the heatbed assembly 26 is independently movable along a vertical Z-axis and the extrusion head 24 is movable in the X, Y plane.

The additive manufacturing system 20 builds three-dimensional objects in the build chamber 22 by depositing the material from extrusion head 24 onto the removable build plate 40 supported on the heatbed assembly 26. The thermal energy from the heatbed assembly 26 maintains the optimal temperature for component fabrication on the removable build plate 40 which is typically magnetically attachable to the heatbed assembly 26.

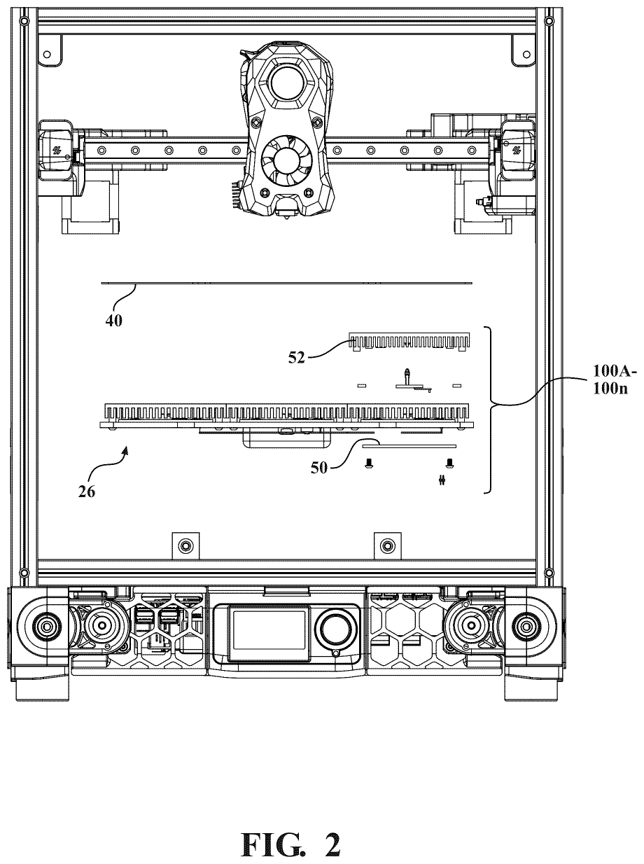

With reference to FIG. 2, the heatbed assembly 26 includes a multiple of cryptocurrency mining chips 50 mounted thereto to generate thermal energy. The cryptocurrency mining chips 50 may include, for example, Application Specific Integrated Circuits (ASICs) and/or Graphical Processing Units (GPUs) designed to perform the complex mathematical calculations (hashing algorithms) required for mining specific cryptocurrencies. This is most broadly used to mine cryptocurrency in the case of ASICs, and for general computing operations in the case of GPUs.

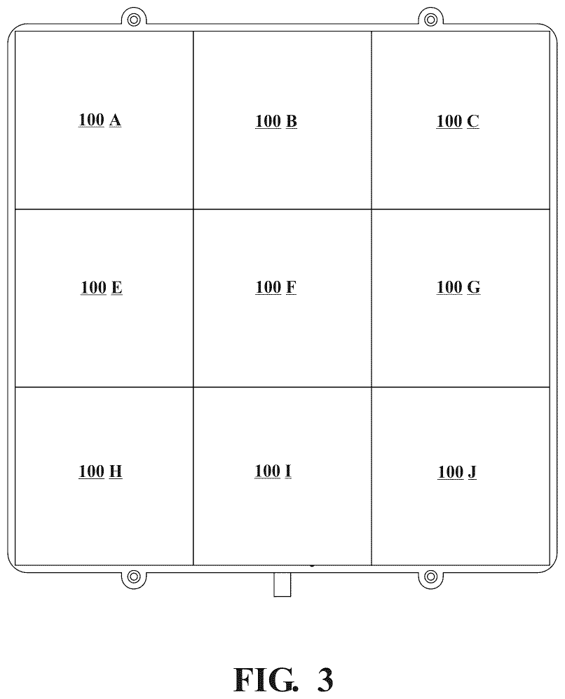

In one embodiment, the heatbed assembly 26 may be assembled from a multiple of tile assemblies 100A-100n (nine shown; FIG. 3). Each of the multiple of cryptocurrency mining chips 50 may be mounted through a heatsink 52 mounted opposite the removable build plate 40 upon which the material from extrusion head 24 is deposited.

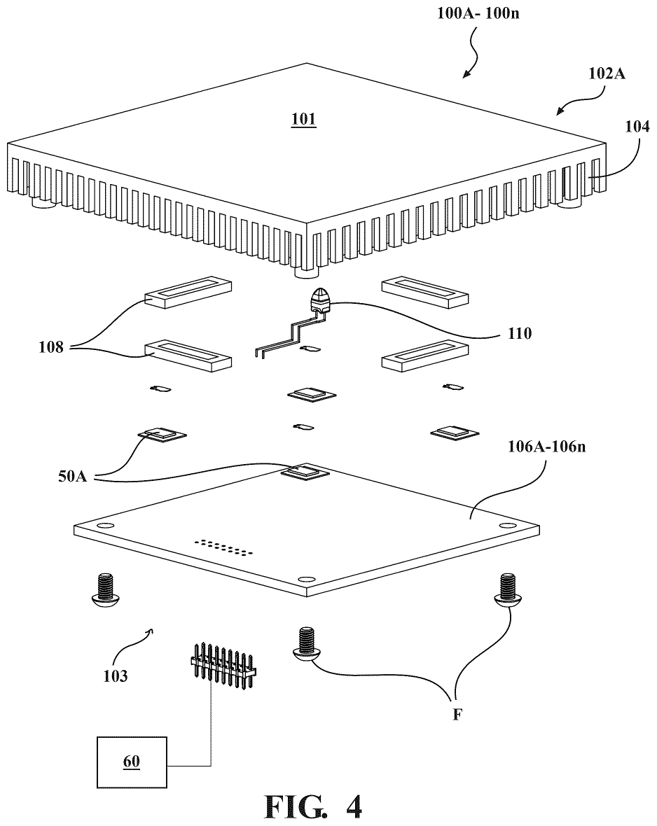

With reference to FIG. 4, each of the multiple of tile assemblies 100A-100n may include a heatsink 102A with a multiple of fins 104, at least one cryptocurrency mining chip 50A (four shown per tile) mounted to a respective cryptocurrency PCB 106A-106n, a multiple of magnets 108, and a sensor 110 such as a thermal probe. The multiple of tile assemblies 100A-100n permits thermal energy to be specifically controlled in each segment of the heatbed assembly 26 as defined by the multiple of tile assemblies 100A-100n.

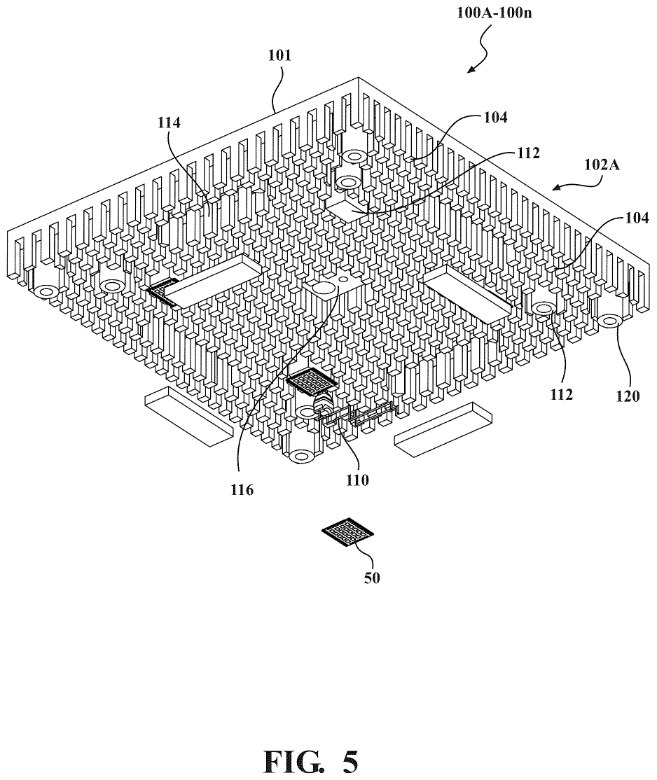

Each of the multiple of tile assemblies 100A-100n may locate the sensor 110 in a central location around which the multiple of cryptocurrency mining chip 50A and multiple of magnets 108 are arranged (FIG. 5). Each of the multiple of magnets 108 may be arranged generally along an edge of each of the tile assemblies 100A-100n to facilitate magnetic retention of the build plate 40.

A chip interface boss 112 (FIG. 5) may be located among the multiple of fins 104. The chip interface boss 112 provides a direct path of contact between each cryptocurrency mining chip 50A and a top surface 101 of each of the respective multiple of tile assemblies 100A-100n to provide a thermal path to the top surface 101. In one embodiment, the cryptocurrency mining chip 50A may be equally spaced along each of the respective multiple of tile assemblies 100A-100n.

A magnet opening 114 (FIG. 5) may be located among the multiple of fins 104 adjacent to a bottom surface 103 of each of the respective multiple of tile assemblies 100A-100n. The magnet opening 114 located among the multiple of fins 104 receives and locates each magnet 108 to provide magnetic retention of the removable build plate 40.

A sensor opening 116 (FIG. 5) may also be located among the multiple of fins 104 in the center of each of the respective multiple of tile assemblies 100A-100n to receive the sensor 110.

A multiple of cryptocurrency PCB interface bosses 118 may also be located among the multiple of fins 104 to provide mounts for the respective PCB 106A-106n which may be removably assembled thereto via fasteners f (FIG. 5).

A multiple of tile assembly interface bosses 120 (FIG. 5) may also be located among the multiple of fins 104 to provide a mount for each of the multiple of tile assemblies 100A-100n.

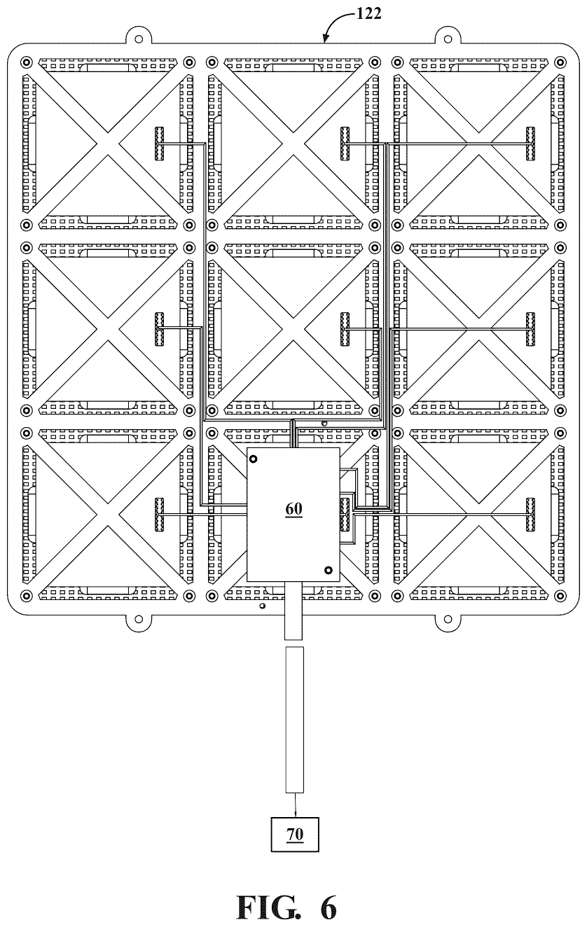

With reference to FIG. 6, a frame 122 of the heatbed assembly 26A supports the multiple of tile assemblies 100A-100n in a rectilinear pattern to form the heatbed assembly 26 of desired dimensions, for example, 277.5 mm×277.5 mm. each of the multiple of tile assemblies 100A-100n may be removably assembled to the multiple of tile assembly interface bosses 120 via fastener (FIG).

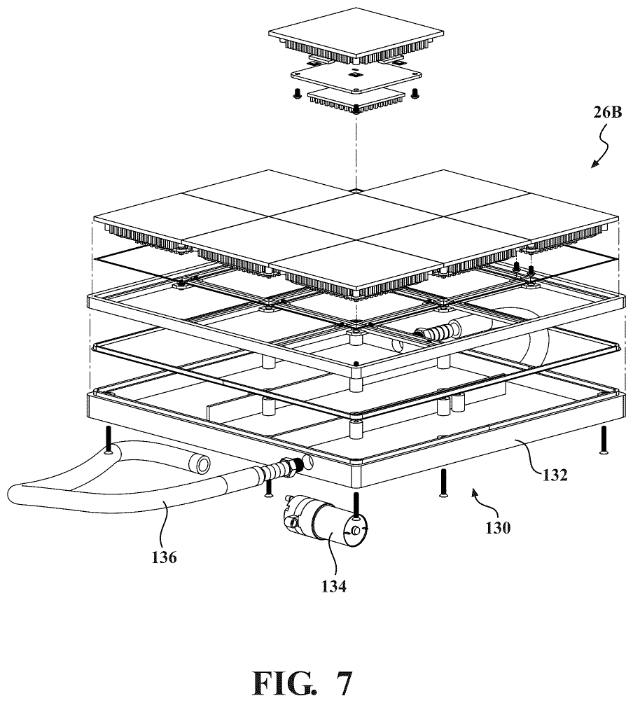

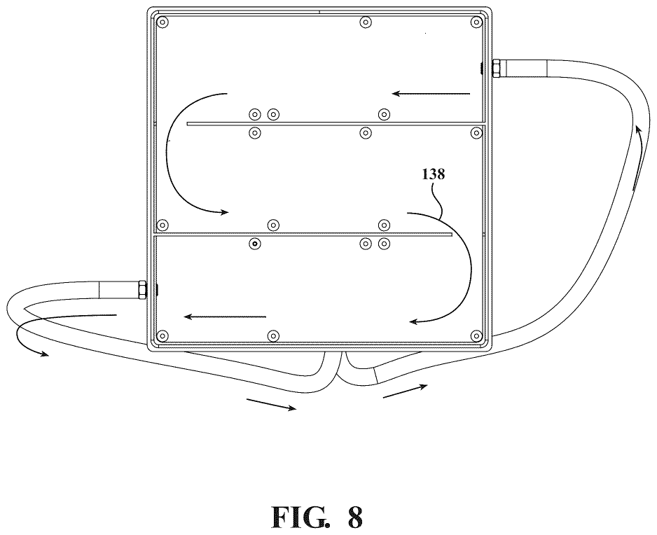

In embodiments, the frame 122 may further support a mining controller 60 to which each of the cryptocurrency PCBs 106A-106n are connected. The mining controller 60 communicates with the additive manufacturing system controller 70. The heatbed assembly 26 is readily incorporated into the heatable build chamber 22. With reference to FIG. 7, in another embodiment, a heatbed assembly 26B includes a thermal management fluid transfer frame system 130. The thermal management fluid transfer frame system 130 generally includes a fluid bath 132, a fluid pump 134 and a fluid hose 136 that forms a continuous fluid flow circuit 138 (FIG. 8) for a di-electric fluid such as, for example, mineral oil, natural ester fluids, and other synthetic hydrocarbons to provide for immersion cooling. Operation of the fluid flow circuit 138 via the fluid pump 134 utilizes the di-electric fluid to cool and thereby control the thermal energy generated by the tile assemblies 100A-100n. In one embodiment, the continuous fluid flow circuit 138 reach a steady sate temperature throughout, somewhere between 50-120 C, but this upper limit may change as chip technology advances. There should be no temperature gradient once the system is operating.

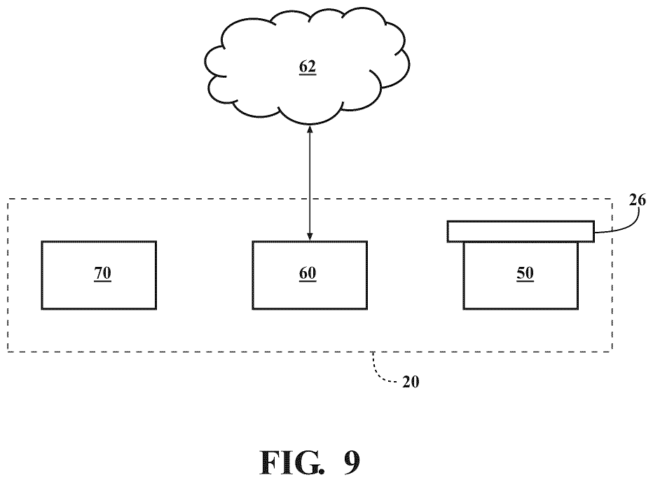

With reference to FIG. 9, the multiple of cryptocurrency mining chips 50 may be in communication with the mining controller 60 to connect with a chosen cryptocurrency network 62 (illustrated schematically) through the additive manufacturing system controller 70 (illustrated schematically) which in one embodiment may include a Proportional-Integral-Derivative (PID) controller. A Proportional-Integral-Derivative (PID) controller may in one example, provide a desired control loop mechanism to automatically control processes through adjustment of a system's output to maintain a desired setpoint by minimizing the error between the desired value (setpoint) and the actual value (measured process variable).

The mining controller 60 and the additive manufacturing system controller 70 may include at least one processor, e.g., microprocessor, microcontroller, digital signal processor, etc., a memory, and an input/output (I/O) interface. The processor and the I/O interface are communicatively coupled to the memory. The memory may be embodied as various forms of ROM, RAM, which stores data and control algorithms such as the logic described herein to control, for example the clock speed of the cryptocurrency mining chips 50. The I/O interface is communicatively coupled to a number of hardware, firmware, and/or software components such as sensors, etc.

The additive manufacturing system controller 70 controls operation of the multiple of cryptocurrency mining chips 50 to generate a desired amount of thermal energy in response to that required by the additive manufacturing system 20. That is, while the additive manufacturing system 20 is operating, the cryptocurrency mining chips 50 are mining cryptocurrency and generating heat. This thermal energy is repurposed to maintain optimal temperature for component fabrication on the heatbed assembly 26 and removable build plate 40.

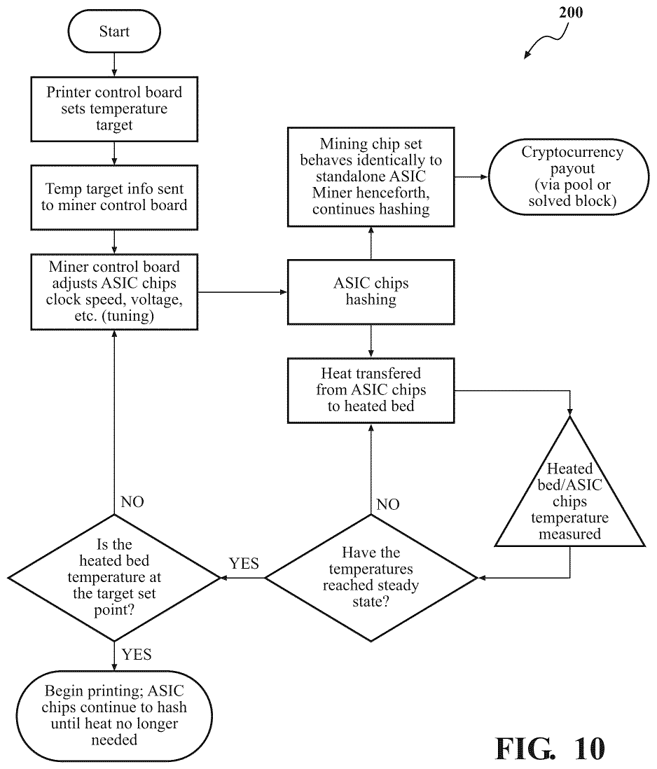

With reference to FIG. 10, a method 200 for operating the additive manufacturing system 20 is schematically illustrated. The functions may be programmed software routines capable of execution in various microprocessor-based electronics control embodiments and are represented herein as block diagrams.

In one embodiment, the thermal energy generated by the multiple of cryptocurrency mining chips 50 is controlled by the additive manufacturing system controller 70 via control of clock speed, voltage, etc. of one or more of the multiple of cryptocurrency mining chips 50 selectively powering specific chips within the array, etc. the additive manufacturing system controller 70 measures a temperature at the heatbed assembly 26 and modifies clock speed, voltage, etc. of one or more of the multiple of cryptocurrency mining chips 50 to maintain a desired temperature.

In other embodiments, the multiple of cryptocurrency mining chips 50 may be controlled in sets such that various portions of the heatbed assembly 26 may be at different temperatures to increase efficiency by only selectively heating portions of the bed with individual chips for smaller components to be made. For example, a 10 cm×10 cm area at the center of the heatbed assembly 26 may be separately heated, for small object printing. The cryptocurrency mining chips and thermal energy heatsinks outside this zone remain idle, saving energy.

In one example, an FDM/FFF (Fused Deposition Modeling/Fused Filament Fabrication) heated heatbed assembly 26 promotes adhesion and prevents warping via thermal energy from the multiple of cryptocurrency mining chips 50 rather than otherwise wasted thermal energy generated via restive elements.

In other embodiments, the multiple of cryptocurrency mining chips 50 may be integrated into an aftermarket plug and play type board that is attachable to the heatbed assembly 26 to replace the restive elements. That is, the heated bed intended for FDM 3D Printing also mines cryptocurrency, for the purposes of generating thermal energy as a desirable product, with cryptocurrency being the “byproduct” of the additive manufacturing which delineates the desired thermal energy therefrom.

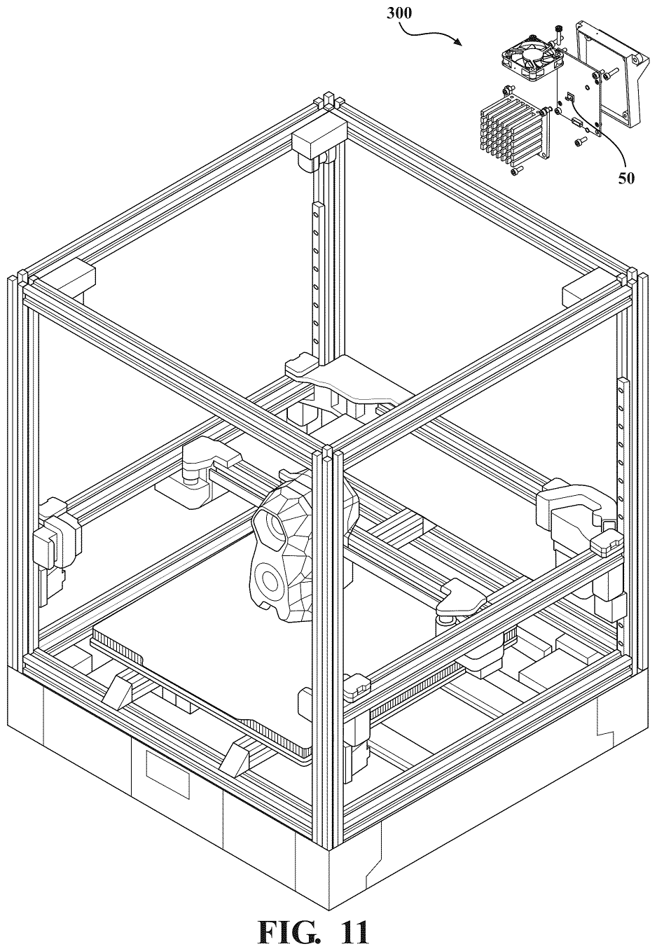

With reference to FIG. 11, in another embodiment, the additive manufacturing system 20 includes an additive manufacturing system chamber heater 300, whereby the ambient thermal energy in the chamber is generated by cryptocurrency mining chips 50 for the purposes of mining cryptocurrency, rather than generated via a resistive element. The additive manufacturing system chamber heater 300 may be modular and include a fan and an outer heat sink arrangement to facilitate airflow movement. The additive manufacturing system chamber heater 300 may be located at various positions within the additive manufacturing system 20.

The computational processing is applied to a cryptocurrency network and mining rewards are paid out to the operator as a byproduct of the additive manufacturing (3D Printing). This provides additional income stream for those operating additive manufacturing systems. The electricity expended via cryptocurrency mining to maintain temperatures are nearly identical to current resistive heating technologies.

Although the different non-limiting embodiments have specific illustrated components, the embodiments of this invention are not limited to those particular combinations. It is possible to use some of the components or features from any of the non-limiting embodiments in combination with features or components from any of the other non-limiting embodiments.

The foregoing description is exemplary rather than defined by the limitations within. Various non-limiting embodiments are disclosed herein, however, one of ordinary skill in the art would recognize that various modifications and variations in light of the above teachings will fall within the scope of the appended claims. It is therefore to be appreciated that within the scope of the appended claims, the disclosure may be practiced other than as specifically described. For that reason the appended claims should be studied to determine true scope and content.

What is claimed:

1. A heatbed assembly for an additive manufacturing system, comprising:
a heatsink; and
a multiple of cryptocurrency mining chips mounted adjacent to the heatsink to transfer thermal energy to the heatsink.

2. The assembly as recited in claim 1, further comprising a 3D printer controller in communication with a cryptocurrency mining chip controller, the 3D printer controller operable to control the multiple of cryptocurrency mining chips in response to a desired temperature.

3. The assembly as recited in claim 2, wherein the heatbed assembly comprises a multiple of tile assemblies.

4. The assembly as recited in claim 3, wherein the multiple of tile assemblies are arranged in a rectilinear pattern.

5. The assembly as recited in claim 3, wherein each of the multiple of tile assemblies comprise a multiple of magnets.

6. The assembly as recited in claim 5, wherein the multiple of cryptocurrency mining chips are mounted to a multiple of printed circuit boards, each of the multiple of printed circuit boards mounted to one of the multiple of tile assemblies.

7. The assembly as recited in claim 6, further comprising a temperature sensor mounted to each of the multiple of tiles, each temperature sensor in communication with the 3D printer controller.

8. The assembly as recited in claim 7, wherein each of the multiple of tile assemblies comprise a multiple of fins of the heatsink.

9. The assembly as recited in claim 7, wherein the multiple of fins comprise a multiple of magnet openings located among the multiple of fins adjacent to a bottom surface of each of the respective multiple of tile assemblies to receive and locates a magnet of the multiple of magnets to provide magnetic retention of a removable build plate.

10. The assembly as recited in claim 9, further comprising a removable build plate magnetically retained to the heatsink.

11. The assembly as recited in claim 7, further comprising a chip interface boss located among the multiple of fins to provides a direct path of contact between one of the multiple of cryptocurrency mining chip a top surface of each of the respective multiple of tile assemblies.

12. The assembly as recited in claim 7, further comprising a multiple of cryptocurrency PCB interface bosses among the multiple of fins to provide mounts for a respective cryptocurrency printed circuit board that comprises a multiple of cryptocurrency mining chips.

13. The assembly as recited in claim 2, further comprising thermal management fluid transfer frame system which circulates a di-electric fluid adjacent to the multiple of cryptocurrency mining chips.

14. A method of heating for an additive manufacturing system, comprising:
controlling operation of a multiple of cryptocurrency mining chips in response to a desired temperature of an additive manufacturing system.

15. The method as recited in claim 14, wherein controlling operation of the cryptocurrency mining chips comprises modifying a clock speed.

16. The method as recited in claim 14, further comprising controlling a circulation of a di-electric fluid adjacent to the multiple of cryptocurrency mining chips.
